(19) United States
(12) Patent Application Publication
(10) Pub. No.: US 2026/0168296 A1
(43) Pub. Date: Jun. 18, 2026

(54) SENSING APPARATUS, A MOBILITY APPARATUS INCLUDING THE SAME, AND A CONTROL METHOD OF A MOBILITY APPARATUS

(71) Applicants: HYUNDAI MOTOR COMPANY, Seoul (KR); KIA CORPORATION, Seoul (KR); Seoul National University R&DB Foundation, Seoul (KR)

(72) Inventors: Moo Seok Kwak, Hwaseong-si (KR); Ji Ho Choi, Hwaseong-si (KR); Dong Jun Kim, Hwaseong-si (KR); Sang Kyun Ahn, Hwaseong-si (KR); Kyoung Taek Kwak, Hwaseong-si (KR); Kwan Hui Kang, Hwaseong-si (KR); Kyeong Jun Lim, Hwaseong-si (KR); Su Hwan Kim, Seoul (KR); Kyoung Won Lim, Yongin-si (KR); Sang Hwa Han, Seoul (KR)

(73) Assignees: HYUNDAI MOTOR COMPANY, Seoul (KR); KIA CORPORATION, Seoul (KR); Seoul National University R&DB Foundation, Seoul (KR)

(21) Appl. No.: 19/404,982

(22) Filed: Dec. 1, 2025

(30) Foreign Application Priority Data
Dec. 17, 2024 (KR) 10-2024-0187804

(51) Int. Cl. E05B 81/76; G01D 5/20; G01D 5/24; H03K 17/96

(52) U.S. Cl. CPC E05B 81/77; G01D 5/20; G01D 5/24; H03K 17/9618; H03K 17/962; H03K 2217/96038

(57) ABSTRACT

A sensing apparatus of a mobility apparatus includes a first touch sensor unit configured to generate a first sensing value in response to a touch and a second touch sensor unit configured to generate a second sensing value in response to the touch. The sensing apparatus also includes a normalization unit configured to normalize the first sensing value to determine a first normalized value and normalize the second sensing value to determine a second normalized value. The sensing apparatus also includes a touch validity determination unit configured to determine a difference value between a maximum peak value of the first normalized value and a maximum peak value of the second normalized value and determine whether the touch is valid based on the difference value.

### CROSS-REFERENCE TO RELATED APPLICATION

This application claims priority to and the benefit of Korean Patent Application No. 10-2024-0187804, filed on Dec. 17, 2024, the entire contents of which are hereby incorporated herein by reference.

### BACKGROUND

### 1. Technical Field

The present disclosure relates to a sensing apparatus, a mobility apparatus including the same, and a control method of the mobility apparatus.

### 2. Discussion of Related Art

As a user interface of a mobility apparatus, a touch sensor unit detects a user's contact and generates an input signal. In the case of the touch sensor unit that has only one way to recognize a user's touch, there is a problem that sensing performance is reduced in some cases. For example, in the case of a capacitive touch sensor unit, sensing values of a user's hand and moisture are similar, so there is a problem in that the sensing sensitivity of the touch sensor unit is lowered in an environment where the touch sensor unit comes into contact with moisture.

For example, in some cases, the touch sensor unit may be installed on a door handle of the mobility apparatus, and there is a problem in that sensing sensitivity decreases when water comes into contact with the touch sensor unit when it is raining or during car washing. To prevent the decrease, a sensing apparatus in which an inductive touch sensor unit is added may be used.

However, even when the capacitive touch sensor unit and the inductive touch sensor unit are combined, in the case of the capacitive touch sensor unit, there is a problem that it is difficult to distinguish between a case where a touch is made by a user's hand and a case where a touch occurs as water continuously drops. In addition, in the case of the inductive touch sensor unit, it is possible to distinguish between a case where a touch is made by a user's hand and a case where a touch occurs as water continuously drops, but there is a problem in that each reference line should be separately provided when determining the validity of a touch operation.

The statements in this Background section merely provide background information related to the present disclosure and do not necessarily constitute prior art.

### SUMMARY

Embodiments of the present disclosure prove a sensing apparatus and a control method capable of preventing an error in sensing due to moisture.

According to an aspect of the present disclosure, a sensing apparatus of a mobility apparatus is provided. The sensing apparatus includes a first touch sensor unit configured to generate a first sensing value in response to a touch, a second touch sensor unit configured to generate a second sensing value in response to the same touch, a normalization unit configured to normalize the first sensing value to calculate a first normalized value and normalize the second sensing value to calculate a second normalized value, and a touch validity determination unit configured to calculate a difference value between a maximum peak value of the first normalized value and a maximum peak value of the second normalized value and determine whether the touch is valid based on the difference value.

A sensing technique of the first touch sensor unit corresponding to the touch and a sensing technique of the second touch sensor unit corresponding to the touch may be different from each other.

The normalization unit may be configured to normalize the first sensing value to determine the first normalized value in a range of about 0.0 to about 1.0, and normalize the second sensing value to determine the second normalized value in the range of about 0.0 to about 1.0.

The first normalized value may be a value obtained by dividing the first sensing value by a first reference value, the second normalized value may be a value obtained by dividing the second sensing value by a second reference value, the first reference value may be a value previously stored in the normalization unit and is a maximum value among the first sensing values by a first touch method (also referred to herein as “touch technique”) that is one of a plurality of touch methods implementing the touch, and the second reference value may be a maximum value among the second sensing values by the first touch method.

The first touch technique may be a touch method in which a user performs the touch with a bare hand and a touch duration time is within a reference time.

The touch validity determination unit may be configured to determine that the touch is invalid based on determining that the difference value exceeds a reference value, and determine that the touch is valid based on determining that the difference value is less than or equal to the reference value.

According to another aspect of the present disclosure, a mobility apparatus including a sensing apparatus is provided. The sensing apparatus includes a first touch sensor unit configured to generate a first sensing value in response to a touch, a second touch sensor unit configured to generate a second sensing value in response to the touch, and a normalization unit configured to normalize the first sensing value to determine a first normalized value and normalize the second sensing value to determine a second normalized value. The sensing apparatus also includes a determination unit configured to determine a difference value between a maximum peak value of the first normalized value and a maximum peak value of the second normalized value and determine whether the touch is valid based on the difference value.

The mobility apparatus may further include a door handle on which the sensing apparatus is disposed, and the first touch sensor unit and the second touch sensor unit may be disposed on the door handle.

According to still another aspect of the present disclosure, a control method is provided. The control method includes generating a first sensing value and a second sensing value in response to one touch. The control method also includes normalizing the first sensing value to determine a first normalized value and normalizing the second sensing value to determine a second normalized value. The control method additionally includes determining a difference value between a maximum peak value of the first normalized value and a maximum peak value of the second normalized value and determining whether the touch is valid based on the difference value.

Normalizing the first sensing value may include determining the first normalized value in a range of about 0.0 to about 1.0. Normalizing the second sensing value may include determining the second normalized value in the range of about 0.0 to about 1.0.

The first normalized value may be a value obtained by dividing the first sensing value by a first reference value, the second normalized value may be a value obtained by dividing the second sensing value by a second reference value, the first reference value may be a value previously stored in a determination unit and is a maximum value among the first sensing values by a first touch method that is one of a plurality of touch methods implementing the touch, and the second reference value may be a maximum value among the second sensing values by the first touch method.

The first touch technique may be a touch method in which a user performs the touch with a bare hand and a touch duration time is within a reference time.

Determining whether the touch is valid includes determining that the touch is invalid based on determining that the difference value exceeds a reference value, and determining that the touch is valid based on determining that the difference value is less than or equal to the reference value.

### BRIEF DESCRIPTION OF THE DRAWINGS

The above and other objects, features, and advantages of the present disclosure should become more apparent to those of ordinary skill in the art by referring to example embodiments thereof in detail with reference to the accompanying drawings, in which:

FIG. 1 is a block diagram illustrating a sensing apparatus according to an implementation;

FIG. 2 is a view illustrating a mobility apparatus including the sensing apparatus according to an implementation;

FIG. 3 is a view illustrating the sensing apparatus according to an implementation;

FIG. 4 is a view illustrating a normalization unit according to an implementation;

FIG. 5 is a graph illustrating a first normalized value when a touch is performed with a bare hand so that a touch duration time is within a reference time according to an implementation;

FIG. 6 is a graph illustrating a first normalized value when a touch occurs as water continuously drops without a touch by a user according to an implementation;

FIG. 7 is a block diagram illustrating a touch validity determination unit according to an implementation;

FIG. 8 is a graph illustrating a difference between a first normalized value and a second normalized value corresponding to a touch that is formed as water continuously drops according to an implementation;

FIG. 9 is a graph illustrating a difference between a first normalized value and a second normalized value corresponding to a touch caused by water cleaning according to an implementation;

FIG. 10 is a flow diagram illustrating a control method of a mobility apparatus according to an implementation; and

FIG. 11 is a flowchart illustrating the control method of a mobility apparatus according to an implementation.

### DETAILED DESCRIPTION

Since the present disclosure may be variously modified and may have various embodiments, particular embodiments thereof are illustrated in the drawings and described below. However, this is not intended to limit the present disclosure to the specific embodiments, and it should be understood to include all modifications, equivalents, and substitutes included in the spirit and scope of the present disclosure.

Although the terms including ordinal numbers such as second, first, or the like, may be used to describe various elements, these elements are not limited by these terms. These terms are only used to distinguish one element from another element. For example, without departing from the scope of the present disclosure, a second element could be termed a first element, and similarly, a first element could be termed a second element. The term “and/or” includes a combination of a plurality of related listed items or any of a plurality of related listed items.

It should be understood that when an element is referred to as being “coupled” or “connected” to another element, the element may be directly coupled or connected to the other element, or one or more intervening elements may also be present. In contrast, it should be understood that when an element is referred to as being “directly coupled” or “directly connected” to another element, there are no intervening elements.

The terms used in the present application are merely provided to describe specific embodiments, and are not intended to limit the present disclosure. The singular forms are intended to include the plural forms as well, unless the context clearly indicates otherwise. In the present disclosure, it should be understood that terms “include,” “have,” or the like are intended to specify the presence of features, integers, steps, operations, elements, components, and/or combinations thereof stated in the specification, but do not preclude the possibility of the presence or addition of one or more other features, integers, steps, operations, elements, components, or combinations thereof in advance.

Unless otherwise defined, all terms used herein, including technical or scientific terms, have the same meaning as commonly understood by those of ordinary skill in the art to which the present disclosure pertains. Terms, such as those defined in commonly used dictionaries, should be interpreted as having a meaning that is consistent with their meaning in the context of the related art and should not be interpreted in an idealized or overly formal sense unless expressly so defined herein.

When a component, controller, device, element, apparatus, unit or the like of the present disclosure is described as having a purpose or performing an operation, function, or the like, the component, controller, device, element, apparatus, unit or the like should be considered herein as being “configured to” meet that purpose or to perform that operation or function. Each component, controller, device, element, apparatus, unit, or the like may separately embody or be included with one or more processors and a memory, such as a non-transitory computer-readable media, as part of the apparatus. The one or more processors may be configured to implement computer-readable instructions stored in the memory to perform the described operations.

The term “˜ unit” used in the present embodiment may mean a software or hardware component such as a field-programmable gate array (FPGA) or an ASIC, and the “unit” performs certain roles. However, the “˜ unit” is not limited to software or hardware. The “˜ unit” may reside on an addressable storage medium and configured to reproduce one or more processors. Therefore, for example, the “˜ unit” may include components such as software components, object-oriented software components, class components, and task components, processes, functions, attributes, procedures, subroutines, segments of program code, drivers, firmware, microcode, circuits, data, database, data structures, tables, arrays, and variables. Functions provided in the components and “˜ units” may be combined into a smaller number of components and “˜ unit” or separated into additional components and “units.” Additionally, the components and “˜ units” may be implemented to reproduce one or more CPUs in a device or a security multimedia card.

Unless otherwise specified, all numbers, values, and/or representations used herein should be taken as approximations and thus should be understood to be modified by the term “about” in all cases. Furthermore, when a numerical range is disclosed in this specification, the range is continuous, and includes all values from the minimum value of said range to the maximum value thereof, unless otherwise indicated. Moreover, when such a range pertains to integer values, all integers including the minimum value to the maximum value are included, unless otherwise indicated.

Hereinafter, embodiments are described in detail with reference to the accompanying drawings. The same or corresponding components are denoted by the same reference numerals regardless of the drawing numbers, and redundant descriptions thereof have been omitted.

In the case of a capacitive touch sensor, since sensing values of water and a user's hand are similar, it is difficult to distinguish between the water and the hand. In the case of an inductive touch sensor, since the sensing values of water and the user's hand are different, it is easy to distinguish between the water and the hand. In each case where a touch is made, a reference value has to be set to determine the validity of the touch. A sensing apparatus according to an embodiment, a mobility apparatus including the same, and a control method of a mobility apparatus determine the validity of a touch operation by identifying a touch due to moisture through one reference value.

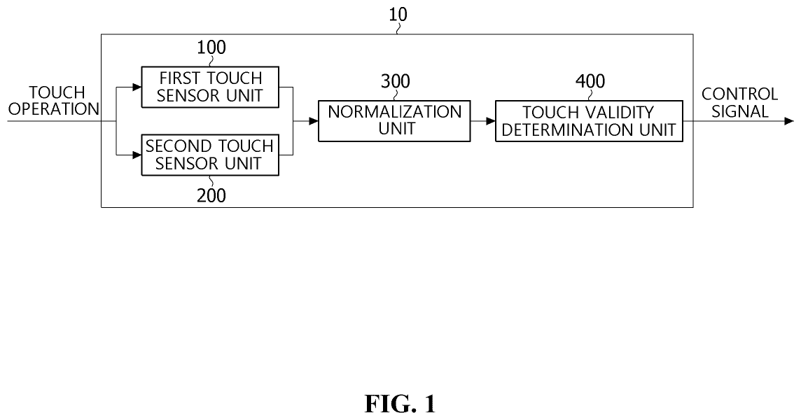

FIG. 1 is a block diagram illustrating a sensing apparatus according to an embodiment.

Referring to FIG. 1, a sensing apparatus 10 according to an embodiment may include a first touch sensor unit 100, a second touch sensor unit 200, a normalization unit 300, and a touch validity determination unit 400.

For one touch, the first touch sensor unit 100 and the second touch sensor unit 200 may detect the touch together. In an embodiment, the touch may be a touch by a user's bare hand, a touch by a gloved hand, a touch by continuously dropping water, or a combination of at least two of the touches. Hereinafter, a touch is defined as a touch that may generate a first sensing value of the first touch sensor unit 100 and a second sensing value of the second touch sensor unit 200 together.

The first touch sensor unit 100 may detect the touch using a capacitive method. The first touch sensor unit may detect a change in capacitance due to an external touch, thereby generating the first sensing value. In addition, the second touch sensor unit 200 may detect the touch using an inductive method. The second touch sensor unit 200 may generate the second sensing value by detecting a change in inductance.

The first touch sensor unit 100 may detect even a small change and thus has high sensing sensitivity, whereas the second touch sensor unit 200 does not accept input when touched with a gloved hand. On the other hand, the second touch sensor unit 200 may receive various types of touch input including, for example, a gloved hand or the like, in addition to a bare hand, and may secure relatively high sensing performance even when touched by dust or water compared to the first touch sensor unit 100. The sensing apparatus 10 may thus secure sensing performance by combining the first touch sensor unit 100 and the second touch sensor unit 200 and utilizing respective advantages.

The normalization unit 300 is connected to each of the first touch sensor unit 100 and the second touch sensor unit 200. The normalization unit 300 may receive the first sensing value from the first touch sensor unit 100 to calculate a first normalized value. In addition, the normalization unit 300 may receive the second sensing value from the second touch sensor unit 200 to calculate a second normalized value. In order to determine the validity of the touch, the normalization unit 300 may perform a preprocessing operation to convert the input sensing values into standardized values and may compare the first sensing value and the second sensing value using the standardized values.

The touch validity determination unit 400 is connected to the normalization unit 300. The touch validity determination unit 400 may receive the first normalized value and the second normalized value from the normalization unit 300. In addition, the touch validity determination unit 400 may determine the validity of the touch based on the first normalized value and the second normalized value, and may generate a control signal corresponding to the touch when the touch is valid.

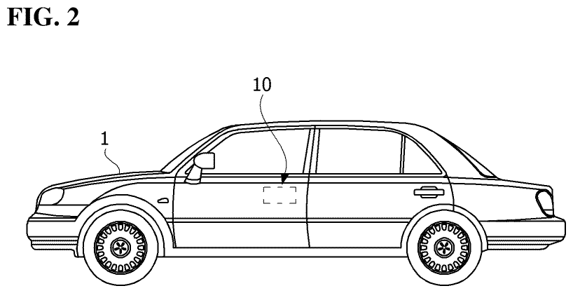

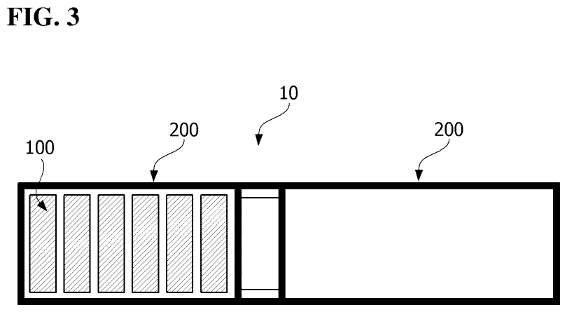

FIG. 2 is a view illustrating a mobility apparatus including the sensing apparatus 10 according to an embodiment. FIG. 3 is a view illustrating the sensing apparatus 10 according to an embodiment.

Referring to FIGS. 2 and 3, the sensing apparatus 10 may be formed to be exposed to the outside of the mobility apparatus. The mobility apparatus may be a vehicle or may be another suitable type of mobility apparatus. In an example, the sensing apparatus 10 may be installed on a door handle of the mobility apparatus. The first touch sensor unit 100 and the second touch sensor unit 200 may be installed on the door handle. The first touch sensor unit 100 and the second touch sensor unit 200 may be positioned adjacent to each other. For example, the first touch sensor unit 100 may be positioned at the center of the door handle. The second touch sensor unit 200 may be formed in a concave portion of the door handle. A portion of the second touch sensor unit 200 may be positioned along a perimeter of the first touch sensor unit 100. Although the first touch sensor unit 100 and the second touch sensor unit 200 have been described by way of example as above, the present disclosure is not limited thereto and may be modified in various shapes and positions. In addition, the position of the sensing apparatus 10 is not limited to the door handle. The sensing apparatus 10 may be installed in various locations of the mobility apparatus in various embodiments.

When the sensing apparatus 10 is positioned outside of the mobility apparatus, when it is raining, water droplets may fall on the sensing apparatus 10, or the user may touch the sensing apparatus 10 with a wet hand. In addition, even when it is not raining, when water is sprayed on the mobility apparatus, for example during water cleaning, water may reach the sensing apparatus 10 at a pressure exceeding a predetermined level. In some embodiments, even when the sensing apparatus 10 is inside a mobility apparatus, water inside the mobility apparatus may come into contact with the sensing apparatus 10.

In such cases, it is difficult to distinguish whether the touch is performed by the user or has occurred by water. Since water is a conductive material, water may be detected as a touch through the first touch sensor unit 100, and when water is sprayed at high pressure, water may be detected as a touch through the second touch sensor unit 200 even when there is no touch from the user.

In order to distinguish the touch, the sensing apparatus 10 according to an embodiment standardizes and compares the first sensing value of the first touch sensor unit 100 and the second sensing value of the second touch sensor unit 200, that occur together by a specific touch, through the normalization unit 300. The sensing apparatus 10 may utilize the result of the comparison to determine the validity of the touch.

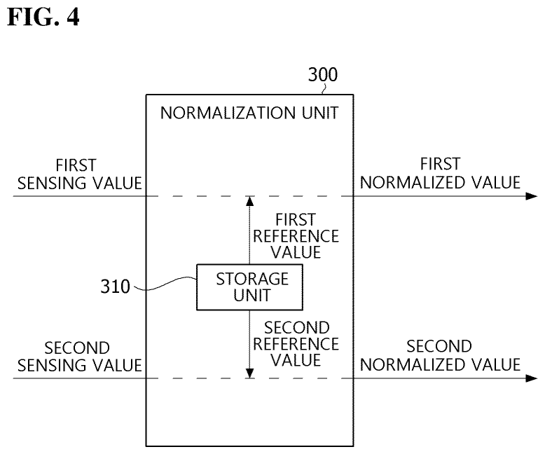

FIG. 4 is a view illustrating the normalization unit 300 according to an embodiment.

Referring to FIG. 4, the normalization unit 300 receives a first sensing value from the first touch sensor unit 100 to calculate or otherwise determine a first normalized value. In addition, the normalization unit 300 receives a second sensing value from the second touch sensor unit 200 to calculate or otherwise determine a second normalized value.

A range of the first sensing value corresponding to a touch may be very large, and a range of the second sensing value corresponding to the touch may also be very large. In addition, the range of the first sensing value and the range of the second sensing value may not match and the difference may be very large. Accordingly, the normalization unit 300 may normalize the first sensing value and the second sensing value using a predetermined standard and may convert the values into standardized values to allow mutual comparison.

The normalization unit 300 may calculate or determine the first normalized value by setting the first sensing value to “1” when the user performs a touch with a bare hand and a touch duration time is within a reference time. In an embodiment, the first normalized value may be calculated based on Equation 1 below.

$$N 1 = S 1 / S 1 a \qquad < Equation 1 >$$

In Equation 1, N1 is a first normalized value, S1 is a first sensing value generated by the first touch sensor unit 100 in response to a touch, and Sla is a maximum value of the first sensing value when the user performs the touch with the bare hand and the touch duration time is within a reference time (first touch method).

When the user performs the touch with the bare hand and the touch duration time is within the reference time, the first sensing value may be a value previously stored in a storage unit 310 of the normalization unit 300. In an embodiment, the reference time may be a short time of less than 1 second.

The normalization unit 300 may calculate or determine the second normalized value by setting the second sensing value to “1” when the user performs a touch with the bare hand and the touch duration time is within a reference time. In an embodiment, the second normalized value may be calculated based on Equation 2 below.

$$N 2 = S 2 / S 2 a \qquad < Equation 2 >$$

In Equation 2, N2 is a second normalized value, S2 is a second sensing value generated by the second touch sensor unit 200 in response to a touch, and S2a is a maximum value of the second sensing value when the user performs the touch with the bare hand and the touch duration time is within a reference time.

When the user performs the touch with the bare hand and the touch duration time is within the reference time, the second sensing value may be a value previously stored in the storage unit 310 of the normalization unit 300. In an embodiment, the reference time may be a short time of less than 1 second.

An example of the normalized value calculated in response to the touch, according to an embodiment, is described in more detail below based on the first normalized value.

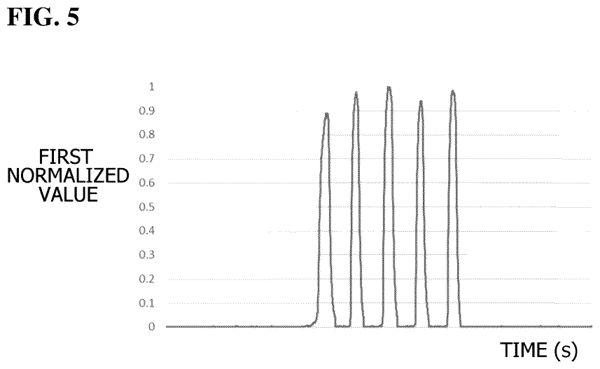

FIG. 5 is a graph illustrating a first normalized value when a touch is performed with a bare hand so that a touch duration time is within a reference time according to an embodiment.

Referring to FIG. 5, when the touch is performed with the bare hand so that the touch duration time is within the reference time, the first normalized value is generally calculated or otherwise determined to be close to “1.” Since the case of a brief touch with bare hands is used as the standard, the first and second normalized values are calculated to be close to “1.”

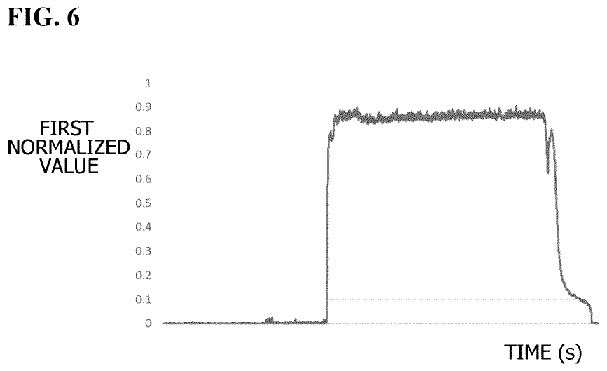

FIG. 6 is a graph illustrating a first normalized value when a touch occurs as water continuously drops without a touch by a user according to an embodiment.

Referring to FIG. 6, when a touch occurs as water continuously drops without a touch by a user, the first normalized value is generally calculated or otherwise determined as “0.9.” The value indicates a value smaller than the first normalized value obtained when the user performs a brief touch with a bare hand. The expression “when a touch occurs as water continuously drops without a touch by a user” may include, for example, cases such as “when rain falls,” “water cleaning is performed,” or “water splashes and touches the sensing apparatus 10 during driving.”

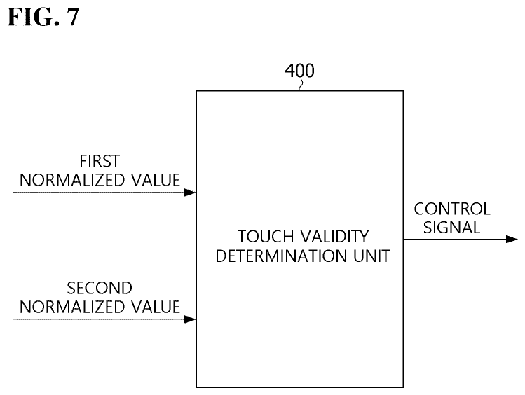

FIG. 7 is a block diagram illustrating the touch validity determination unit 400 according to an embodiment.

Referring to FIG. 7, the touch validity determination unit 400 determines whether a touch is valid. In an embodiment, it is possible to check whether a touch detected by the sensing apparatus 10 is a touch by a user or a touch by water, and when it is determined that the touch is a touch by the user, a corresponding control signal may be generated. The sensing apparatus may then control the mobility apparatus based on the control signal. As just an example, the control signal may be a control signal for unlocking a door of the mobility apparatus. The sensing apparatus may provide the control signal to a lock on the door of the mobility apparatus to unlock the door of the mobility apparatus.

The touch validity determination unit 400 may receive a first normalized value and a second normalized value from the normalization unit 300. In addition, the touch validity determination unit 400 may detect each of a maximum peak value of the first normalized value and a maximum peak value of the second normalized value. In addition, the touch validity determination unit 400 may determine whether a difference value between the detected maximum peak value of the first normalized value and the detected maximum peak value of the second normalized value exceeds a reference value. When the difference value exceeds the reference value, the touch validity determination unit 400 may determine that the touch is not a valid touch. On the other hand, when the difference value does not exceed the reference value, the touch validity determination unit 400 may determine that the touch is a valid touch and generate a corresponding control signal. In an embodiment, the reference value may be a preset value.

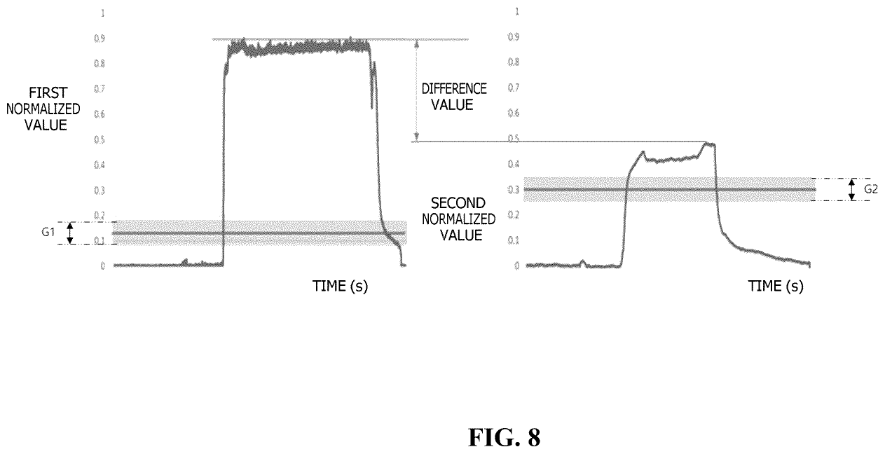

FIG. 8 is a graph illustrating a difference between a first normalized value and a second normalized value corresponding to a touch that is formed as water continuously drops according to an embodiment.

Referring to FIG. 8, the first normalized value may generally be formed between 0.8 and 0.9 in response to a touch that is formed as water continuously drops. The touch validity determination unit 400 may detect a maximum peak value of the first normalized value as 0.93 when the touch is formed as water continuously drops.

In addition, the second normalized value may generally be formed between 0.4 and 0.5 in response to the touch that is formed as the water continuously drops. The touch validity determination unit 400 may detect a maximum peak value of the second normalized value as 0.49 when the touch is formed as water continuously drops.

Looking at a reference in the related art, in response to the touch that is formed as the water continuously drops, based on the first normalized value, a reference value is set to 0.13 and within a range of a specified width G1. Accordingly, when the reference value is applied to the touch that is formed as the water continuously drops without a touch by a user, since the first normalized value may be formed between 0.8 and 0.9, which greatly exceeds the reference value of 0.13, it may be determined that the touch is a valid touch even without a touch by the user.

In addition, looking at the reference in the related art, in response to the touch that is formed as the water continuously drops, based on the second normalized value, a reference value is set to 0.3 and within a range of a specified width G2. Accordingly, when the reference value is applied to the touch that is formed as the water continuously drops without a touch by a user, since the second normalized value may be formed between 0.4 and 0.5, which exceeds the reference value of 0.3, it may be determined that the touch is a valid touch even without a touch by the user.

On the other hand, with the sensing apparatus 10 according to an embodiment, when the difference value between 0.93, which is the maximum peak value of the first normalized value, and 0.49, which is the maximum peak value of the second normalized value, is 0.44 and the reference value is 0.4, the touch validity determination unit 400 may determine that the corresponding touch is an invalid touch since the difference value is greater than the reference value. Accordingly, the touch validity determination unit 400 may determine that the touch is a touch by water without the touch by the user and invalidate the corresponding touch.

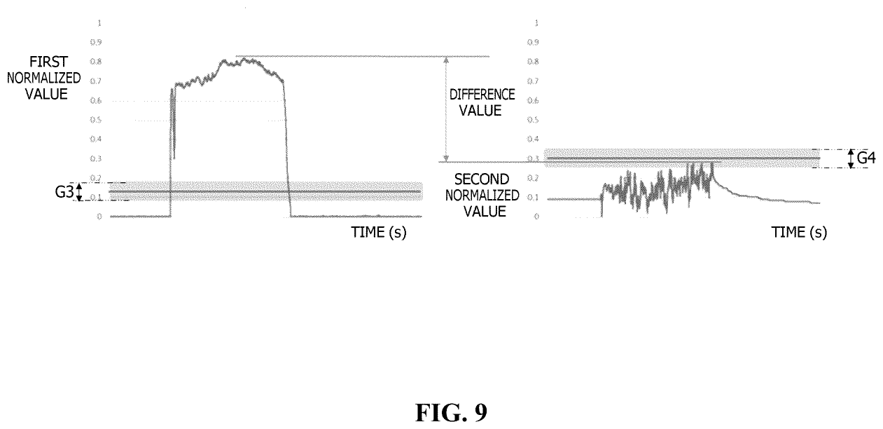

FIG. 9 is a graph illustrating a difference between a first normalized value and a second normalized value corresponding to a touch caused by water cleaning according to an embodiment.

Referring to FIG. 9, the first normalized value is generally formed between 0.7 and 0.8 in response to the touch caused by water cleaning. In the case of water cleaning, the touch validity determination unit 400 may detect a maximum peak value of the first normalized value as 0.82.

In addition, the second normalized value is generally formed between 0.1 and 0.3 in response to the touch caused by water cleaning. In the case of water cleaning, the touch validity determination unit 400 may detect a maximum peak value of the second normalized value as 0.28.

Looking at a reference in the related art, in response to the touch caused by water cleaning, based on the first normalized value, a reference value is set to 0.13 and within a range of a specified width G3. Accordingly, when the reference value is applied to the touch caused by water cleaning, since the first normalized value may be formed between 0.7 and 0.8, which greatly exceeds the reference value of 0.13, it may be determined that the touch is a valid touch.

In addition, looking at the reference in the related art, in response to the touch caused by water cleaning, based on the second normalized value, a reference value is set to 0.3 and within a range of a specified width G4. When the reference value is applied to the touch caused by water cleaning, since the second normalized value may be formed between 0.1 and 0.3, which does not exceed the reference value of 0.3, it may be determined that the touch is an invalid touch.

On the other hand, with the sensing apparatus 10 according to an embodiment, when the difference value between 0.82, which is the maximum peak value of the first normalized value, and 0.28, which is the maximum peak value of the second normalized value, is 0.54 and the reference value is 0.4, the touch validity determination unit 400 may determine that the corresponding touch is an invalid touch since the difference value is greater than the reference value. Accordingly, the touch validity determination unit 400 may determine that the touch is a touch by water without the touch by the user and invalidate the corresponding touch.

As illustrated in Table 1 below, the validity of a corresponding touch may be determined by various touches.

TABLE 1

| | | | Case | Case | Case | Case |
|---|---|---|---|---|---|---|
| | | | 2 | 3 | 4 | 5 |
| Comparative | Capacitive type | High | High | High | High | High |
| example | touch sensor | | | | | |
| | Reference | | | | | |
| | value (0.13 ± | | | | | |
| | 0.05) | | | | | |
| | Inductive | High | High | High | High | High |
| | touch sensor | | | | | |
| | reference | | | | | |
| | value (0.3 ± | | | | | |
| | 0.05) | | | | | |

| | | | | | |
|---|---|---|---|---|---|
| Validity determination of | Valid | Valid | Valid | Valid | Valid |
| comparative example | | | | | |
| Difference value of example | 0.19 | −0.16 | 0.21 | 0.13 | 0.44 |
| (Reference value 0.4) | | | | | |
| Validity determination of | Valid | Valid | Valid | Valid | Invalid |
| example | | | | | |

In Table 1, Case 1 is a case in which a user performs a touch with a bare hand for a short period of time. In Case 1, a comparative example is that a normalized reference value in the capacitive touch sensor is set to 0.13±0.05, and when a normalized sensing value is greater than or equal to the reference value, it is determined that a touch is a valid touch. In addition, a normalized reference value in the inductive touch sensor is set to 0.3±0.05, and when a normalized sensing value is greater than or equal to the reference value, it is determined that a touch is a valid touch.

When the user performs a touch with a bare hand within a short period of time, it is determined that the validity of the touch is valid in both types of sensors, and thus, in Case 1, the comparative example and the example show the same result.

In Table 1, Case 2 is a case where the user performs a long touch with a bare hand, Case 3 is a case where the user performs a short touch with a gloved hand, and Case 4 is a case where the user performs a long touch with the gloved hand. In Cases 2 to 4, it is determined that the validity of the touches is valid in both types of sensors just like in Case 1, and thus the comparative example and the example show the same result.

In the case of the example, when there are touches by the user, it is determined that all touches are valid.

In Table 1, Case 5 is a case where a touch occurs as water continuously drops. In Case 5, in the comparative example, since the normalized sensing values are found to be greater than or equal to the reference value in both the capacitive touch sensor and the inductive touch sensor, it is determined that the touch is a valid touch. However, in the example, since the difference value is 0.44, which exceeds the reference value of 0.4, it is determined that the touch is an invalid touch. Accordingly, in the comparative example, it is determined that the touch is a valid touch even though there is no user touch, whereas in the case of the example, it may be confirmed that it is checked that there is no user touch and the touch is determined as invalid.

As illustrated in Table 2 below, the validity of the corresponding touch may be determined by various touches.

TABLE 2

| | | Case 6 | Case 7 | Case 8 | Case 9 | Case 10 |
|---|---|---|---|---|---|---|
| Comparative | Capacitive type | High | Similar | Similar | Low | High |
| example | touch sensor | | | | | |
| | Reference value | | | | | |
| | (0.13 ± 0.05) | | | | | |
| | Inductive touch | High | High | High | High | Low |
| | sensor reference | | | | | |
| | value (0.3 ± 0.05) | | | | | |

| | | | | | |
|---|---|---|---|---|---|
| Validity determination of | Valid | Ambiguous | Ambiguous | Ambiguous | Ambiguous |
| comparative example | | | | | |
| Difference value of example | −0.34 | *0.34 | −0.6 | −0.29 | 0.54 |
| (Reference value 0.4) | | | | | |
| Validity determination of example | Valid | Valid | Valid | Valid | Invalid |

In Table 2, Case 6 is a case where the user performs a brief touch with the bare hand in the state where water continuously drops, Case 7 is a case where the user performs a long touch with the bare hand in the state where water continuously drops, Case 8 is a case where the user performs a brief touch with the gloved hand in the state where water continuously drops, and Case 9 is a case where the user performs a long touch with the gloved hand in the state where water continuously drops.

In Case 6, all touches are found to be valid in the touch validity determination, and thus the comparative example and the example show the same result. In Cases 7 to 9, the validity of the touch is shown as ambiguous. On the other hand, in the case of the example, when there is a touch by the user in Cases 6 to 9, it is determined that the touch is valid.

In Table 2, Case 10 is a case where water is sprayed at high pressure and a touch occurs during cleaning. In Case 10, the comparative example shows that in the capacitive touch sensor, the sensing value is greater than or equal to the reference value, whereas in the inductive touch sensor, the sensing value is smaller than the reference value, so that the determination of the touch is found to be ambiguous. However, in the example, since the difference value is 0.54, which exceeds the reference value of 0.4, it is determined that the touch is an invalid touch. That is, in the comparative example, it may not be definitely determined that the touch is a valid touch even though there is no user touch, whereas in the case of the example, it may be confirmed that it is checked that there was no user touch and the touch is determined as invalid.

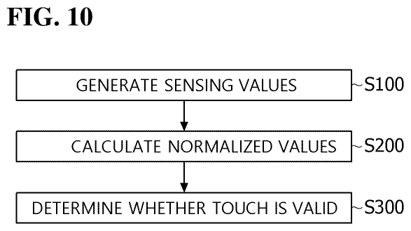

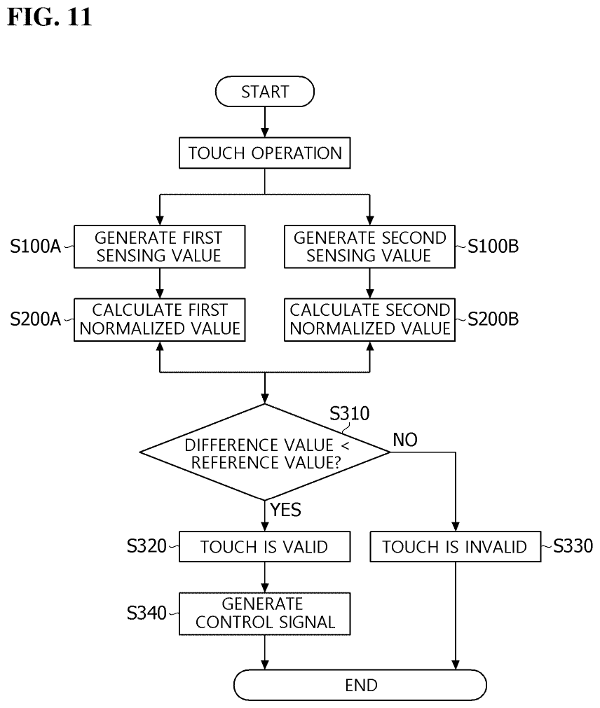

FIG. 10 is a flow diagram illustrating a control method of a mobility apparatus according to an embodiment. FIG. 11 is a flowchart illustrating the control method of a mobility apparatus according to an embodiment.

Referring to FIGS. 10 and 11, in an operation S100, the control method of a mobility apparatus generates sensing values. For a touch, in an operation S100A, the first touch sensor unit 100 generates a first sensing value. For the same touch, in an operation S100B, the second touch sensor unit 200 generates a second sensing value.

In an operation S200, the normalization unit 300 calculates or otherwise determines normalized values. In an operation S200A, the normalization unit 300 receives the first sensing value from the first touch sensor unit 100 to calculate or otherwise determine a first normalized value. In an operation S200B, the normalization unit 300 receives the second sensing value from the second touch sensor unit 200 to calculate a second normalized value.

In an operation S300, the touch validity determination unit 400 determines whether the touch is valid. The touch validity determination unit 400 may receive the first normalized value and the second normalized value from the normalization unit 300. The touch validity determination unit 400 may detect each of a maximum peak value of the first normalized value and a maximum peak value of the second normalized value. In an operation S310, the touch validity determination unit 400 determines whether a difference value between the detected maximum peak value of the first normalized value and the detected maximum peak value of the second normalized value exceeds a reference value. When the difference value exceeds the reference value, in an operation S330, the touch validity determination unit 400 may determine that the touch is not a valid touch. On the other hand, the touch validity determination unit 400 determines, in an operation S320, that the touch is a valid touch when the difference value does not exceed the reference value.

The touch validity determination unit 400 may generate a control signal corresponding to the touch when it is determined that the touch is valid.

According to embodiments of the present disclosure, there is an advantage in that it is possible to clearly distinguish whether a touch is caused by moisture or by a user's touch.

Although example embodiments of the present disclosure have been described above, it should understood that those having ordinary skill in the art can make various changes and modifications to the present disclosure without departing from the spirit and scope of the present disclosure set forth in the claims below.

What is claimed is:

1. A sensing apparatus of a mobility apparatus, the sensing apparatus comprising:
a first touch sensor unit configured to generate a first sensing value in response to a touch;
a second touch sensor unit configured to generate a second sensing value in response to the touch;
a normalization unit configured to normalize the first sensing value to determine a first normalized value and normalize the second sensing value to determine a second normalized value; and
a touch validity determination unit configured to determine a difference value between a maximum peak value of the first normalized value and a maximum peak value of the second normalized value and determine whether the touch is valid based on the difference value.

2. The sensing apparatus of claim 1, wherein a sensing technique of the first touch sensor unit corresponding to the touch and a sensing technique of the second touch sensor unit corresponding to the touch are different from each other.

3. The sensing apparatus of claim 1, wherein the normalization unit is configured to:
normalize the first sensing value to determine the first normalized value in a range of about 0.0 to about 1.0; and
normalize the second sensing value to determine the second normalized value in the range of about 0.0 to about 1.0.

4. The sensing apparatus of claim 3, wherein:
the first normalized value is a value obtained by dividing the first sensing value by a first reference value;
the second normalized value is a value obtained by dividing the second sensing value by a second reference value;
the first reference value is a value previously stored in the normalization unit and is a maximum value among first sensing values corresponding to a first touch technique that is one of a plurality of touch techniques of implementing the touch; and
the second reference value is a maximum value among second sensing values corresponding to a second touch technique among the plurality of touch techniques of implementing the touch.

5. The sensing apparatus of claim 4, wherein the first touch technique is a touch technique in which a user performs the touch with a bare hand and a touch duration time is within a reference time.

6. The sensing apparatus of claim 1, wherein the touch validity determination unit is configured to:
determine that the touch is invalid based on determining that the difference value exceeds a reference value; and
determine that the touch is valid based on determining that the difference value is less than or equal to the reference value.

7. A mobility apparatus comprising a sensing apparatus,
wherein the sensing apparatus includes:
a first touch sensor unit configured to generate a first sensing value in response to a touch;
a second touch sensor unit configured to generate a second sensing value in response to the touch;
a normalization unit configured to normalize the first sensing value to calculate a first normalized value and normalize the second sensing value to calculate a second normalized value; and
a touch validity determination unit configured to determine a difference value between a maximum peak value of the first normalized value and a maximum peak value of the second normalized value and determine whether the touch is valid based on the difference value.

8. The mobility apparatus of claim 7, wherein a sensing technique of the first touch sensor unit corresponding to the touch and a sensing technique of the second touch sensor unit corresponding to the touch are different from each other.

9. The mobility apparatus of claim 7, wherein the normalization unit is configured to:
normalize the first sensing value to determine the first normalized value in a range of about 0.0 to about 1.0; and
normalize the second sensing value to determine the second normalized value in the range of about 0.0 to about 1.0.

10. The mobility apparatus of claim 9, wherein:
the first normalized value is a value obtained by dividing the first sensing value by a first reference value;
the second normalized value is a value obtained by dividing the second sensing value by a second reference value;
the first reference value is a value previously stored in the normalization unit and is a maximum value among first sensing values corresponding to a first touch technique that is one of a plurality of touch techniques of implementing the touch; and
the second reference value is a maximum value among second sensing values corresponding to a second touch technique among the plurality of touch techniques of implementing the touch.

11. The mobility apparatus of claim 10, wherein the first touch technique is a touch technique in which a user performs the touch with a bare hand and a touch duration time is within a reference time.

12. The mobility apparatus of claim 7, wherein the touch validity determination unit is configured to:
determine that the touch is invalid based on determining that the difference value exceeds a reference value; and
determines that the touch is valid based on determining that the difference value is less than or equal to the reference value.

13. The mobility apparatus of claim 7, further comprising a door handle on which the sensing apparatus is disposed,
wherein the first touch sensor unit and the second touch sensor unit are disposed on the door handle.

14. A control method comprising:
generating a first sensing value and a second sensing value in response to one touch;
normalizing the first sensing value to determine a first normalized value;
normalizing the second sensing value to determine a second normalized value;
determining a difference value between a maximum peak value of the first normalized value and a maximum peak value of the second normalized value; and
determining whether the touch is valid based on the difference value.

15. The control method of claim 14, wherein:
normalizing the first sensing value includes determining the first normalized value in a range of about 0.0 to about 1.0; and
normalizing the second sensing value includes determining the second normalized value in the range of about 0.0 to about 1.0.

16. The control method of claim 15, wherein:
the first normalized value is a value obtained by dividing the first sensing value by a first reference value;
the second normalized value is a value obtained by dividing the second sensing value by a second reference value;
the first reference value is a value previously stored and is a maximum value among first sensing values corresponding to a first touch technique that is one of a plurality of touch techniques of implementing the touch; and
the second reference value is a maximum value among second sensing values corresponding to a second touch technique among the plurality of touch techniques of implementing the touch.

17. The control method of claim 16, wherein the first touch technique is a touch technique in which a user performs the touch with a bare hand and a touch duration time is within a reference time.

18. The control method of claim 14, wherein determining whether the touch is valid includes:
determining that the touch is invalid based on determining that the difference value exceeds a reference value; and
determining that the touch is valid based on determining that the difference value is less than or equal to the reference value.
